(19) United States
(12) Patent Application Publication
(10) Pub. No.: US 2024/0113035 A1
(43) Pub. Date: Apr. 4, 2024

(54) SEMICONDUCTOR DEVICE, BASE-SIDE SEMICONDUCTOR CHIP, AND BONDING-SIDE SEMICONDUCTOR CHIP

(71) Applicants: LAPIS TECHNOLOGY CO., LTD., Yokohama (JP); LAPIS SEMICONDUCTOR CO., LTD., Kanagawa (JP)

(72) Inventors: JUNICHI IKEDA, KANAGAWA (JP); KAZUYUKI HONDA, KANAGAWA (JP)

(21) Appl. No.: 18/371,546

(22) Filed: Sep. 22, 2023

(30) Foreign Application Priority Data
Sep. 30, 2022 (JP) 2022-158227

(51) Int. Cl. H01L 23/544; H01L 25/065

(52) U.S. Cl. CPC H01L 23/544; H01L 25/0657; H01L 24/16; H01L 2223/54426; H01L 2225/06513; H01L 2225/06593; H01L 2225/06596

(57) ABSTRACT

A semiconductor device includes: a first semiconductor chip on which a first alignment mark, a second alignment mark, first and second terminals for measuring conduction, a wiring that electrically connects the first alignment mark and the first terminal, and a wiring that electrically connects the second alignment mark and the second terminal are provided; and a second semiconductor chip on which a third alignment mark, a fourth alignment mark, and a wiring that electrically connects the third alignment mark and the fourth alignment mark are provided and which is bonded to the first semiconductor chip in such a way that the first alignment mark and the third alignment mark overlap each other, and the second alignment mark and the fourth alignment mark overlap each other.

### CROSS-REFERENCE TO RELATED APPLICATION

This application is based on and claims priority under 35 USC 119 from Japanese Patent Application No. 2022-158227 filed on Sep. 30, 2022, the disclosures of which are incorporated by reference herein.

### BACKGROUND

### Technical Field

The present disclosure relates to a semiconductor device, a base-side semiconductor chip, and a bonding-side semiconductor chip.

### Related Art

Japanese Patent Application Laid-Open (JP-A) No. 2002-111148 (Patent Literature 1) discloses a technology that enables highly reliable flip-chip mounting. In addition, Japanese Patent Application Laid-Open (JP-A) No. 2004-20550 (Patent Literature 2) discloses a technology capable of inspecting electrical connection between a plurality of semiconductor integrated circuit chips in a state where the semiconductor integrated circuit chips are bonded.

Here, in an inspection method of inspecting electrical connection between semiconductor integrated circuit chips according to the related art, inspection is performed by operating an internal circuit included in a semiconductor chip, and it takes time to end the inspection.

### SUMMARY

Therefore, an object of the present disclosure is to reduce an inspection time for inspecting electrical connection between a plurality of semiconductor chips in a state where the semiconductor chips are bonded.

A semiconductor device of the present disclosure includes: a first semiconductor chip on which a first alignment mark, a second alignment mark, first and second terminals for measuring conduction, a wiring that electrically connects the first alignment mark and the first terminal, and a wiring that electrically connects the second alignment mark and the second terminal are provided; and a second semiconductor chip on which a third alignment mark, a fourth alignment mark, and a wiring that electrically connects the third alignment mark and the fourth alignment mark are provided and which is bonded to the first semiconductor chip in such a way that the first alignment mark and the third alignment mark overlap each other, and the second alignment mark and the fourth alignment mark overlap each other.

A base-side semiconductor chip of the disclosure includes: a plurality of base-side alignment marks; measurement terminals for measuring conduction; and wirings that electrically connect the base-side alignment marks and the measurement terminals, in which the measurement terminals are configured to measure conduction in a case where a bonding-side semiconductor chip is bonded in such a way that the base-side alignment marks and a plurality of bonding-side alignment marks provided on the bonding-side semiconductor chip overlap each other.

A bonding-side semiconductor chip of the disclosure includes: a plurality of bonding-side alignment marks; and a wiring that electrically connects the bonding-side alignment marks to each other, in which in a case where the bonding-side semiconductor chip is bonded to a base-side semiconductor chip in such a way that the bonding-side alignment marks and a plurality of base-side alignment marks provided on the base-side semiconductor chip and electrically connected to measurement terminals for measuring conduction overlap each other, the wiring electrically connects the base-side alignment marks to each other.

According to the present disclosure, it is possible to reduce an inspection time for inspecting electrical connection between a plurality of semiconductor chips in a state where the semiconductor chips are bonded.

### BRIEF DESCRIPTION OF THE DRAWINGS

FIG. 1 is a plan view of a base-side chip;

FIG. 2 is a plan view of a bonding-side chip; and

FIG. 3 is a plan view of a semiconductor device.

### DETAILED DESCRIPTION

Hereinafter, examples of an embodiment of the present disclosure will be described with reference to the drawings. In the drawings, the same or equivalent components and portions are denoted by the same reference signs. In addition, dimensional ratios in the drawings are exaggerated for convenience of explanation, and may be different from actual ratios.

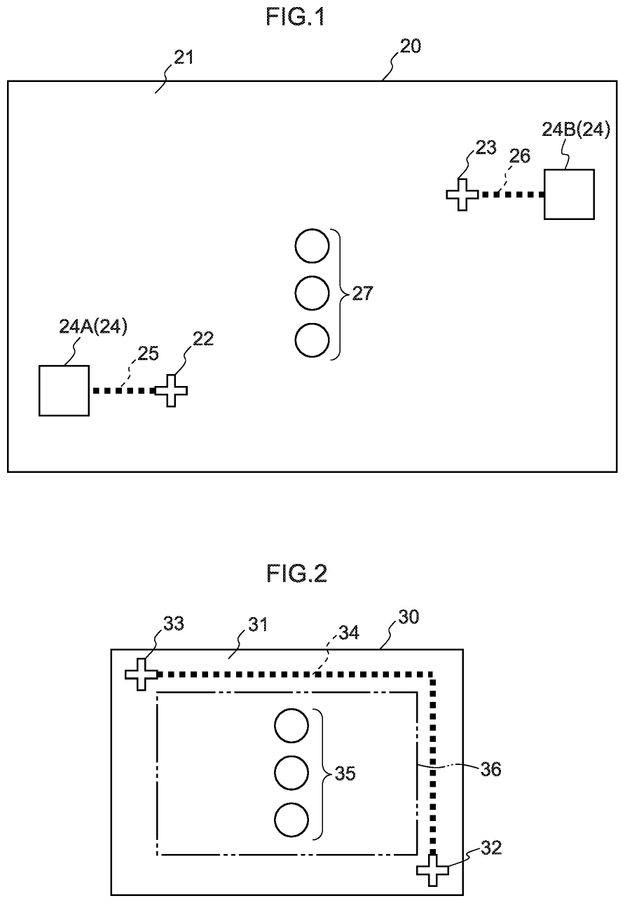

FIG. 1 is a plan view of a base-side semiconductor chip (hereinafter, referred to as a “base-side chip 20”).

As illustrated in FIG. 1, in the base-side chip 20, a first alignment mark 22 arranged on the lower left side in the drawing, a second alignment mark 23 arranged on the upper right side in the drawing, measurement terminals 24 for measuring conduction, and a connection terminal 27 for connection to a bonding-side semiconductor chip (hereinafter, referred to as a “bonding-side chip 30”) are provided on one surface of a semiconductor laminated body 21 having a rectangular shape of which a long side is along the horizontal direction in the drawing and a short side is along the vertical direction in the drawing. The measurement terminals 24 include a first terminal 24A and a second terminal 24B. The first alignment mark 22 and the first terminal 24A are electrically connected by a wiring 25, and the second alignment mark 23 and the second terminal 24B are electrically connected by a wiring 26. The base-side chip 20 is an example of a “first semiconductor chip” and the “base-side semiconductor chip”, the first alignment mark 22 and the second alignment mark 23 are an example of “base-side alignment marks”, and the wiring 25 and the wiring 26 are an example of “wirings that electrically connect the base-side alignment marks and the measurement terminals”.

The first alignment mark 22 and the second alignment mark 23 are made of copper (Cu) and have a cross shape.

The measurement terminal 24 is made of a conductor such as aluminum or aluminum to which copper is added, and has a square shape. Among the measurement terminals 24, the first terminal 24A is arranged on the left side of the first alignment mark 22 in FIG. 1, and the second terminal 24B is arranged on the right side of the second alignment mark 23 in FIG. 1.

The connection terminal 27 is made of copper and has a circular shape. As an example, a plurality of connection terminals 27 are arranged side by side in the vertical direction in the drawing at the central portion of one surface of the laminated body 21. Although only three connection terminals 27 are illustrated in FIG. 1 for convenience of explanation, the number of connection terminals 27 provided on the base-side chip 20 is not limited.

Although methods for manufacturing the first alignment mark 22, the second alignment mark 23, the measurement terminals 24, the wiring 25, the wiring 26, and the connection terminal 27 are not described above, these manufacturing methods are not particularly limited, and known technologies are used if appropriate.

FIG. 2 is a plan view of a bonding-side chip 30.

As illustrated in FIG. 2, in the bonding-side chip 30, a third alignment mark 32 arranged at the lower right in the figure, a fourth alignment mark 33 arranged on the upper left side in the drawing, and a connection terminal 35 for connection to the base-side chip 20 are provided on one surface of a semiconductor laminated body 31 having a rectangular shape of which a long side is along the horizontal direction in the drawing and a short side is along the vertical direction in the drawing. The third alignment mark 32 and the fourth alignment mark 33 are electrically connected by a wiring 34.

The bonding-side chip 30 is an example of a “second semiconductor chip” and the “bonding-side semiconductor chip”, the third alignment mark 32 and the fourth alignment mark 33 are an example of “bonding-side alignment marks”, and the wiring 34 is an example of a “wiring electrically connecting the bonding-side alignment marks”.

The third alignment mark 32 and the fourth alignment mark 33 are made of copper, and have a cross shape similarly to the first alignment mark 22 and the second alignment mark 23. The dimensions of the third alignment mark 32 and the fourth alignment mark 33 are substantially the same as the dimensions of the first alignment mark 22 and the second alignment mark 23.

The third alignment mark 32 and the fourth alignment mark 33 are arranged in such a way that the first alignment mark 22 and the third alignment mark 32 overlap each other, and the second alignment mark 23 and the fourth alignment mark 33 overlap each other in a case where the bonding-side chip 30 is reversed from the state illustrated in FIG. 2 and overlaps the base-side chip 20.

The wiring 34 is arranged outside a semiconductor element region 36 provided at the central portion of the bonding-side chip 30. Although not illustrated, a semiconductor or the like necessary for operation of a semiconductor device 10 in which the bonding-side chip 30 is bonded to the base-side chip 20 is arranged in the element region 36.

The connection terminal 35 is made of copper and has a circular shape similarly to the connection terminal 27. As an example, a plurality of connection terminals 35 are arranged side by side in the vertical direction in the drawing at the central portion of one surface of the laminated body 31. The connection terminal 35 is arranged in such a way that the connection terminal 27 and the connection terminal 35 overlap each other in a case where the bonding-side chip 30 is reversed from the state illustrated in FIG. 2 and overlaps the base-side chip 20. Although only three connection terminals 35 are illustrated in FIG. 2 for convenience of explanation, the number of connection terminals 35 provided on the bonding-side chip 30 is not limited.

Although methods for manufacturing the third alignment mark 32, the fourth alignment mark 33, the wiring 34, and the connection terminal 35 are not described above, these manufacturing methods are not particularly limited, and known technologies are used if appropriate.

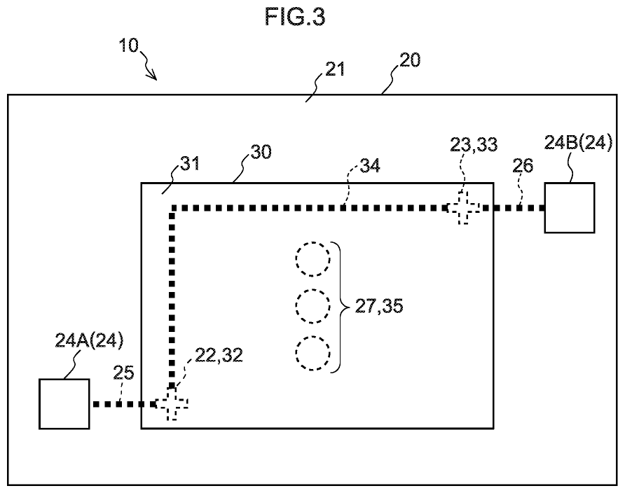

FIG. 3 is a plan view of the semiconductor device 10 in which the bonding-side chip 30 is bonded to the base-side chip 20.

The base-side chip 20 and the bonding-side chip 30 are bonded (joined) by, for example, Cu—Cu bonding between the connection terminal 27 and the connection terminal 35. In a state where the bonding-side chip 30 is bonded to the base-side chip 20, the first alignment mark 22 and the third alignment mark 32 overlap each other, and the second alignment mark 23 and the fourth alignment mark 33 overlap each other. The alignment between the first alignment mark 22 and the third alignment mark 32 and the alignment between the second alignment mark 23 and the fourth alignment mark 33 are achieved using a known technology if appropriate.

Here, in the semiconductor device 10, in a case where the bonding-side chip 30 is bonded to the base-side chip 20 as described above, conduction can be measured using the measurement terminals 24. Specifically, as illustrated in FIG. 3, in the semiconductor device 10, as the bonding-side chip 30 is bonded to the base-side chip 20, the wiring 34 of the bonding-side chip 30 can electrically connect the first alignment mark 22 and the second alignment mark 23 to each other. In the semiconductor device 10, the measurement terminals 24 (the first terminal 24A and the second terminal 24B) are electrically connected to each other in a case where the first alignment mark 22 and the second alignment mark 23 are electrically connected to each other.

Incidentally, in a case where the semiconductor device 10 is manufactured by bonding a plurality of semiconductor chips to each other as in the present embodiment, it is desirable to inspect (test) whether or not the semiconductor chips are electrically connected to each other. Then, in the semiconductor device 10 in which the base-side chip 20 and the bonding-side chip 30 are bonded to each other by Cu—Cu bonding, copper is flattened by a chemical mechanical polishing (CMP) process, and thus, it is possible to confirm electrical connection between all the other connection terminals 27 and 35 by confirming electrical connection between a set of connection terminals 27 and 35.

In the embodiment, whether or not the base-side chip 20 and the bonding-side chip 30 are electrically connected to each other is inspected using a probe card (not illustrated) including a needle that is brought into contact with the measurement terminal 24 to input an electric signal to the measurement terminal 24. Specifically, in the embodiment, when a positive (+) voltage (for example, 1 V) is applied to the first terminal 24A and a voltage similar to the voltage applied to the first terminal 24A is measured at the second terminal 24B, it is determined that the base-side chip 20 and the bonding-side chip 30 are electrically connected to each other. In a case where it is determined that the base-side chip 20 and the bonding-side chip 30 are electrically connected to each other, a slight error between the voltage applied to the first terminal 24A and the voltage measured at the second terminal 24B is allowed. On the other hand, in the embodiment, in a case where the voltage measured at the second terminal 24B deviates from the voltage applied to the first terminal 24A by more than the above-described error, it is determined that the base-side chip 20 and the bonding-side chip 30 are not electrically connected to each other.

Here, examples of a conventional inspection method of inspecting whether or not a plurality of bonded semiconductor chips are electrically connected to each other include a method of performing inspection by operating an internal circuit included in a semiconductor chip. For example, in the inspection method, an external device inputs a predetermined signal between a plurality of semiconductor chips, logical computation is performed in an internal circuit included in the semiconductor chip based on the input signal, and whether or not the plurality of semiconductor chips are electrically connected to each other is determined according to the computation result. In this case, it takes time to end the inspection because, for example, the external device is controlled to input the predetermined signal between the plurality of semiconductor chips and the logic computation is performed in the internal circuit included in the semiconductor chip in the inspection method.

On the other hand, in the semiconductor device 10, it is possible to confirm whether or not the base-side chip 20 and the bonding-side chip 30 are electrically connected to each other only by applying a positive (+) voltage to one (first terminal 24A) of the measurement terminals 24 and measuring a voltage at the other one (second terminal 24B) of the measurement terminals 24. Therefore, with the semiconductor device 10, it is possible to reduce an inspection time for inspecting electrical connection between the plurality of semiconductor chips in a state where the semiconductor chips are bonded as compared with the conventional inspection method.

In the semiconductor device 10, the first alignment mark 22, the second alignment mark 23, the third alignment mark 32, and the fourth alignment mark 33 are different in shape from the connection terminal 27, the connection terminal 35, and the measurement terminal 24. As a result, with the semiconductor device 10, it is possible to reduce erroneous image recognition in a case where the bonding-side chip 30 is bonded to the base-side chip 20.

In the semiconductor device 10, the first terminal 24A and the second terminal 24B as the measurement terminals 24 have smaller dimensions than other terminals (not illustrated) required for the operation of the semiconductor device 10. Examples of the other terminals include a bonding pad for connecting a bonding wire. As a result, with the semiconductor device 10, it is possible to reduce an influence of provision of the measurement terminal 24 as compared with a case where the measurement terminal 24 and the other terminals have the same size.

In the semiconductor device 10, the wiring 34 that electrically connects the third alignment mark 32 and the fourth alignment mark 33 is arranged outside the semiconductor element region 36 in the bonding-side chip 30. Therefore, with the semiconductor device 10, it is possible to prevent the wiring 34 from hindering formation of a semiconductor in the element region 36.

(Others)

The material of each member in the above embodiment is not particularly limited. For example, in the above embodiment, the first alignment mark 22, the second alignment mark 23, the third alignment mark 32, the fourth alignment mark 33, the connection terminal 27, and the connection terminal 35 are formed of copper, but are not limited thereto, and may be formed of another metal such as gold (Au).

The shape of each member in the above embodiment is not particularly limited. For example, in the above embodiment, the first alignment mark 22, the second alignment mark 23, the third alignment mark 32, and the fourth alignment mark 33 are formed in a cross shape. However, the disclosure is not limited thereto, and the first alignment mark 22, the second alignment mark 23, the third alignment mark 32, and the fourth alignment mark 33 may be formed in another shape generally used as an alignment mark, such as a circular shape or a ring shape.

What is claimed is:

1. A semiconductor device comprising:
a first semiconductor chip on which a first alignment mark, a second alignment mark, first and second terminals for measuring conduction, a first wiring that electrically connects the first alignment mark and the first terminal, and a second wiring that electrically connects the second alignment mark and the second terminal, are disposed; and
a second semiconductor chip on which a third alignment mark, a fourth alignment mark, and a third wiring that electrically connects the third alignment mark and the fourth alignment mark, are disposed, and which is bonded to the first semiconductor chip such that the first alignment mark and the third alignment mark overlap, and the second alignment mark and the fourth alignment mark overlap.

2. The semiconductor device according to claim 1, wherein the first alignment mark, the second alignment mark, the third alignment mark, and the fourth alignment mark are different in shape from a connection terminal for connecting the first semiconductor chip and the second semiconductor chip to each other.

3. The semiconductor device according to claim 1, wherein the first terminal and the second terminal are smaller in dimension than other terminals required for operation of the semiconductor device.

4. The semiconductor device according to claim 1, wherein the third wiring that electrically connects the third alignment mark and the fourth alignment mark is arranged outside a semiconductor element region of the second semiconductor chip.

5. A base-side semiconductor chip comprising:
a plurality of base-side alignment marks;
measurement terminals for measuring conduction; and
wirings that electrically connect the base-side alignment marks and the measurement terminals,
wherein the measurement terminals are configured to measure conduction in a case where a bonding-side semiconductor chip is bonded such that the base-side alignment marks and a plurality of bonding-side alignment marks provided on the bonding-side semiconductor chip overlap.

6. A bonding-side semiconductor chip comprising:
a plurality of bonding-side alignment marks; and
a wiring that electrically connects the bonding-side alignment marks to each other,
wherein, in a case in which the bonding-side semiconductor chip is bonded to a base-side semiconductor chip such that the bonding-side alignment marks overlap with a plurality of base-side alignment marks that are provided on the base-side semiconductor chip and are electrically connected to measurement terminals for measuring conduction, the wiring electrically connects the base-side alignment marks to each other.
